(19) United States
(12) Patent Application Publication
(10) Pub. No.: US 2026/0099657 A1
(43) Pub. Date: Apr. 9, 2026

(54) GENERATION METHOD AND GENERATION DEVICE OF INTEGRATED CIRCUIT MODEL DATA SET

(71) Applicant: REALTEK SEMICONDUCTOR CORP., HSINCHU (TW)

(72) Inventors: Hao-Wei Cheng, HSINCHU (TW); YING-CHIEH CHEN, HSINCHU (TW); MEI-LI YU, HSINCHU (TW); YU-LAN LO, HSINCHU (TW)

(21) Appl. No.: 19/014,416

(22) Filed: Jan. 9, 2025

(30) Foreign Application Priority Data
Oct. 8, 2024 (TW) 113138194

(51) Int. Cl. G06F 30/33

(52) U.S. Cl. CPC G06F 30/33

(57) ABSTRACT

A generation method and a generation device of an integrated circuit model data set. The generation method includes: obtaining multiple reference model data sets; generating a reference data trend, and determining a key region according to a target parameter value of a target parameter; obtaining multiple filtered model data sets according to the reference data trend and the key region; and inputting the filtered model data sets into a recursive machine learning model. The recursive machine learning model sequentially executes an interpolation procedure and an extrapolation procedure. In the interpolation procedure, an interpolation model data set is generated according to the filtered model data sets. In the extrapolation procedure, an extrapolation model data set that corresponds to the target parameter value is generated according to the filtered model data sets and the interpolation model data set, and is configured as a target model data set.

### CROSS-REFERENCE TO RELATED PATENT APPLICATION

This application claims the benefit of priority to Taiwan Patent Application No. 113138194, filed on Oct. 8, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a method and a device, and more particularly to a generation method and a generation device of an integrated circuit model data set.

### BACKGROUND OF THE DISCLOSURE

In a conventional design process of a circuit, whether or not the designed circuit meets design specifications in terms of timing and power is to be determined. Thus, when performance analysis is carried out during a static timing analysis (STA) process, integrated circuit model data sets (e.g., liberty variation format models) that are under different conditions of process, voltage, and temperature (PVT) and generated during a process of library re-characterization (library re-K) need to be cooperatively used.

However, in order to generate integrated circuit model data sets of different process parameter combinations (process corners), it is necessary for the integrated circuit model data sets under different conditions of PVT to undergo numerous transistor-level simulations (e.g., HSPICE). As a result, a large amount of time (which may take as long as several months) is wasted.

Therefore, how to provide the required integrated circuit model data sets in a more efficient manner and also ensure that the integrated circuit model data sets have certain accuracy and reliability during application in the STA process has become one of the important issues to be solved in the relevant industry.

### SUMMARY OF THE DISCLOSURE

In response to the above-referenced technical inadequacies, the present disclosure provides a generation method and a generation device of an integrated circuit model data set.

In order to solve the above-mentioned problems, one of the technical aspects adopted by the present disclosure is to provide a generation method of an integrated circuit model data set, which is performed by a generation device that includes a processor and a memory. The generation method includes processes of: obtaining a plurality of reference model data sets that correspond to different parameter combinations; analyzing the reference model data sets to generate a reference data trend, and determining a key region according to a target parameter value of a target parameter; obtaining a plurality of filtered model data sets after the reference model data sets are filtered according to the reference data trend and the key region; and inputting the filtered model data sets into a recursive machine learning model. The recursive machine learning model is configured to sequentially execute an interpolation procedure and an extrapolation procedure, so as to generate a target model data set. In the interpolation procedure, the recursive machine learning model generates an interpolation model data set according to the filtered model data sets. In the extrapolation procedure, the recursive machine learning model generates an extrapolation model data set that corresponds to the target parameter value according to the filtered model data sets and the interpolation model data set, and the extrapolation model data set is configured as the target model data set.

In order to solve the above-mentioned problems, another one of the technical aspects adopted by the present disclosure is to provide a generation device of an integrated circuit model data set, which includes at least one processor and a memory. The at least one processor is configured to access the memory and execute processes of: obtaining a plurality of reference model data sets that correspond to different parameter combinations; analyzing the reference model data sets to generate a reference data trend, and determining a key region according to a target parameter value of a target parameter; obtaining a plurality of filtered model data sets after the reference model data sets are filtered according to the reference data trend and the key region; and inputting the filtered model data sets into a recursive machine learning model. The recursive machine learning model is configured to sequentially execute an interpolation procedure and an extrapolation procedure, so as to generate a target model data set. In the interpolation procedure, the recursive machine learning model generates an interpolation model data set according to the filtered model data sets. In the extrapolation procedure, the recursive machine learning model generates an extrapolation model data set that corresponds to the target parameter value according to the filtered model data sets and the interpolation model data set, and the extrapolation model data set is configured as the target model data set.

Therefore, in the generation method and the generation device of the integrated circuit model data set provided by the present disclosure, the recursive machine learning model can be used to produce a high-precision integrated circuit model data set by way of interpolation and extrapolation. Accordingly, simulation time and computing resources can be saved, and a design schedule of an integrated circuit can be accelerated.

Furthermore, since the generation method and the generation device of the present disclosure can provide the high-precision integrated circuit model data set at an early design and development stage of a circuit, back-and-forth debugging can be reduced, and a schedule for modifying the circuit can be shortened. The designed circuit can also closely reflect an actual analysis result thereof, thereby having improved efficacy, power consumption, and area performance.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a functional block diagram of a generation device of an integrated circuit model data set according to one embodiment of the present disclosure;

FIG. 2 is a flowchart of a generation method of the integrated circuit model data set according to one embodiment of the present disclosure;

FIG. 3 is a schematic diagram of a reference data trend according to one embodiment of the present disclosure;

FIG. 4 is a flowchart of step S23 in detail; and

FIG. 5 to FIG. 8 are each a schematic diagram showing trend analysis according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

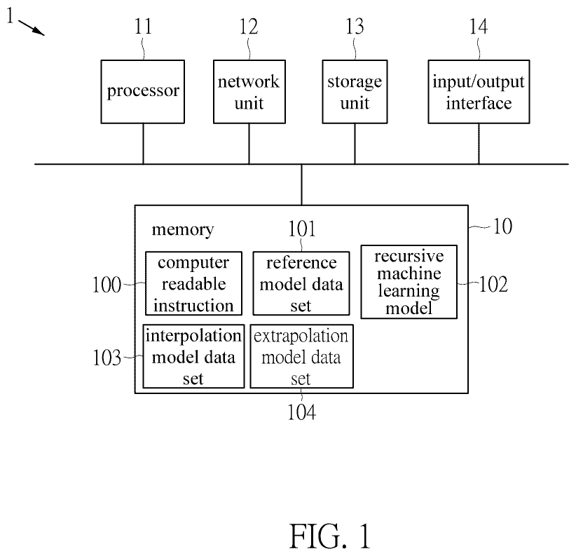

FIG. 1 is a functional block diagram of a generation device of an integrated circuit model data set according to one embodiment of the present disclosure. As shown in FIG. 1, one embodiment of the present disclosure provides a generation device 1 of the integrated circuit model data set, and the generation device 1 includes a memory 10, a processor 11, a network unit 12, a storage unit 13, and an input/output interface 14. The above-mentioned components can communicate with each other by, for example but not limited to, a busbar.

The memory 10 can be any storage device that stores data. The memory 10 is, for example, a random access memory (RAM), a read-only memory (ROM), a flash memory, a hard disk, or other storage devices that are capable of storing data, but is not limited thereto. The memory 10 is configured to at least store multiple computer readable instructions 100. In one embodiment, the memory 10 is also configured to store temporary data generated during computation of the processor 11.

The processor 11 is electrically coupled to the memory 10, and is configured to access the computer readable instructions 100 via the memory 10, so as to execute each step in a generation method of the integrated circuit model data set mentioned in the following descriptions.

The network unit 12 is configured to have network access under the control of the processor 11. The storage unit 13 is, for example but not limited to, a magnetic disk or an optical disk, and can store data or instructions under the control of the processor 11. The input/output device 14 can be operated by a user to communicate with the processor 11, so as to input and output data.

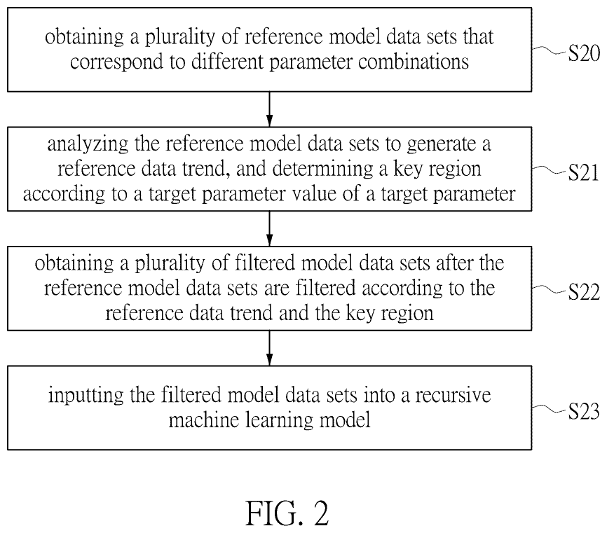

FIG. 2 is a flowchart of the generation method of the integrated circuit model data set according to one embodiment of the present disclosure. The generation method shown in FIG. 2 can be applied to the generation device 1 shown in FIG. 1, or can be implemented by other hardware components (such as a database, a common processor, a calculator, or a server), other unique hardware devices having specific logic circuits, or other apparatuses having specific functions. For example, a program code and a processor/chip can be integrated into unique hardware. Specifically, the generation method can be implemented by a computer program, so as to control each component of the generation device 1. The computer program is stored in a non-transitory computer-readable storage medium, such as a read-only memory, a flash memory, a floppy disk, a hard disk, an optical disk, a flash drive, a magnetic tape, a network-accessible database, or a computer-readable storage medium that can be easily considered by those skilled in the art to have the same function.

FIG. 2 shows the flowchart of the generation method of the integrated model data set according to one embodiment of the present disclosure, and said generation method includes the following steps.

Step S20: obtaining a plurality of reference model data sets that correspond to different parameter combinations.

A plurality of reference model data sets 101 are stored in the memory 10. Each parameter combination includes a process parameter value, a voltage parameter value, and a temperature parameter value that respectively correspond to a process parameter, a voltage parameter, and a temperature parameter. Each reference model data set can be provided by a supplier, and includes circuit timing data of a designed circuit under specific processes, voltages, and/or temperatures (PVT). However, the present disclosure is not limited thereto. Each reference model data set can also include circuit power data of the designed circuit under the specific PVT. In this step, a reasonable quantity of the reference model data sets is three or more, so that a data trend can be analyzed in subsequent steps and an interpolation or extrapolation procedure can be executed.

Step S21: analyzing the reference model data sets to generate a reference data trend, and determining a key region according to a target parameter value of a target parameter.

In step S21, the target parameter is, for example, the process parameter, the voltage parameter, or the temperature parameter. The reference model data sets have a plurality of reference parameter values that correspond to the target parameter. For example, the reference model data sets include multiple pieces of model data (such as timing data) in which the process parameter is FF (fast-fast), the temperature parameter is 120° C., and the voltage parameter is 0.5 V, 0.6 V, or 0.7 V. As such, the model data that corresponds to the reference parameter values of the reference model data sets can be obtained and configured as the reference data trend.

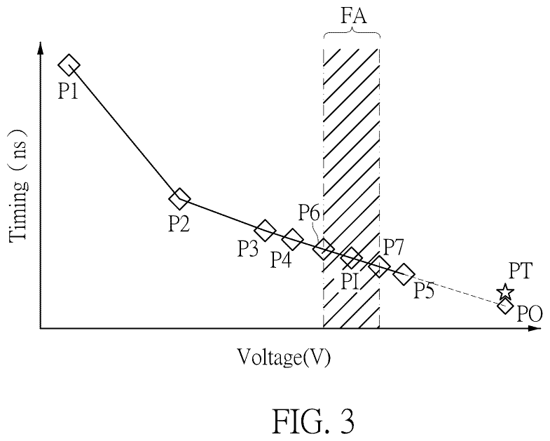

Reference is made to FIG. 3, which is a schematic diagram of the reference data trend according to one embodiment of the present disclosure. As shown in FIG. 3, by illustrating the modal data (such as timing data) that corresponds to the reference parameter values of the reference model data sets as a diagram of timing versus voltage, the reference data trend formed by connection of five rhombus-shaped data points P1 to P5 can be obtained. The target parameter can be, for example, the voltage parameter, and the target parameter value (e.g., a voltage value) is outside of a range of the reference parameter values. Here, an ideal timing value that corresponds to the target parameter value is supposed to be known, and is represented by a star-shaped data point PT.

Generally, if the timing value that corresponds to the target parameter value is estimated by using the reference data trend formed by connection of all rhombus-shaped data points, loss of accuracy may occur. Thus, in step S21, a key region FA is firstly obtained. The key region FA can be, for example, defined by two of the reference parameter values closest to the target parameter value. Taking FIG. 3 as an example, the key region FA is defined by rhombus-shaped data points P6, P7 closest to the star-shaped data point PT.

Step S22: obtaining a plurality of filtered model data sets after the reference model data sets are filtered according to the reference data trend and the key region. According to the reference data trend, the two reference parameter values (e.g., the rhombus-shaped data points P6, P7) closest to the target parameter value can be identified among the reference parameter values, and two of the reference model data sets that correspond to the rhombus-shaped data sets P6, P7 are taken and configured as the filtered model data sets.

Step S23: inputting the filtered model data sets into a recursive machine learning model.

A recursive machine learning model 102 can be stored in the memory 10. It should be noted that, in step S23, the recursive machine learning model 102 is a trained model, and is configured to sequentially execute an interpolation procedure and an extrapolation procedure for generating a target model data set.

In the interpolation procedure, the recursive machine learning model 102 generates an interpolation model data set 103 according to the filtered model data sets. In the extrapolation procedure, the recursive machine learning model 102 generates an extrapolation model data set 104 that corresponds to the target parameter value according to the filtered model data sets and the interpolation model data set 103. The extrapolation model data set 104 is configured as the target model data set. Detailed steps will be further illustrated below.

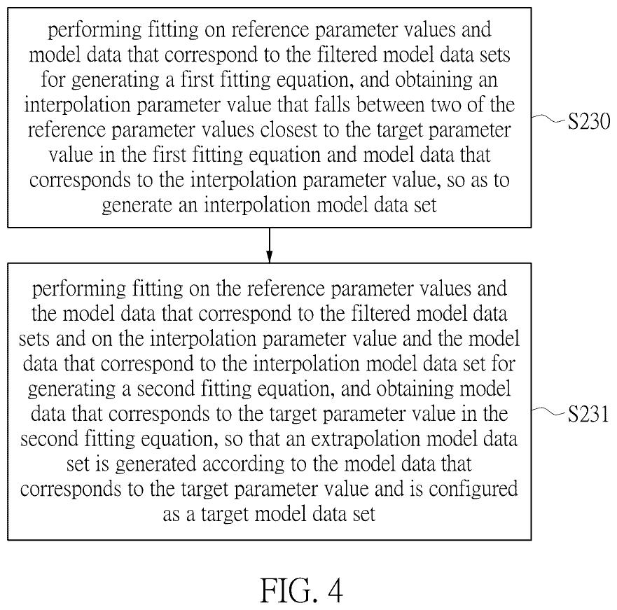

Reference is made to FIG. 4, which is a flowchart of step S23 in detail. In step S23, the recursive machine learning model 102 further executes the following steps.

Step S230: performing fitting on the reference parameter values and the model data that correspond to the filtered model data sets for generating a first fitting equation, and obtaining an interpolation parameter value that falls between the two reference parameter values closest to the target parameter value in the first fitting equation and model data that corresponds to the interpolation parameter value, so as to generate an interpolation model data set.

Reference is made to FIG. 3. In step S230, the interpolation model data set 103 has an interpolation parameter value (e.g., a timing value) that corresponds to the target parameter (the voltage parameter) and a specific process parameter (e.g., a fast-fast (FF), slow-fast (SF), slow-slow (SS), fast-slow (FS), or typical-typical (TT) process parameter). The interpolation parameter value is represented by an interpolation data point P1. The interpolation parameter value that corresponds to the interpolation data point P1 falls between the two reference parameter values (i.e., the rhombus-shaped data points P6, P7) closest to the target parameter value. In addition, the first fitting equation can be, for example, a linear equation (e.g., y=ax+b) or a quadratic equation (e.g., y=ax²+bx+c). However, the present disclosure is not limited thereto.

In the present disclosure, as shown in FIG. 3, adding data points in the key region FA can improve the accuracy of the integrated circuit model data set generation by way of extrapolation in the subsequent steps.

Step S231: performing fitting on the reference parameter values and the model data that correspond to the filtered model data sets and on the interpolation parameter value and the model data that correspond to the interpolation model data set for generating a second fitting equation, and obtaining model data that corresponds to the target parameter value in the second fitting equation, so that the extrapolation model data set is generated according to the model data that corresponds to the target parameter value and is configured as the target model data set.

Taking FIG. 3 as an example, the unselected rhombus-shaped data points P1 to P5 are firstly excluded, and only the rhombus-shaped data points P6, P7 and the interpolation data point PI are retained for a fitting process, so as to generate the second fitting equation. Then, the model data (which is represented by an extrapolation data point PO) that corresponds to the target parameter value in the second fitting equation can be obtained by way of extrapolation. For example, such model data is timing data (e.g., a timing value) that corresponds to the target parameter value (the voltage parameter value) and a specific process parameter (e.g., an FF, SF, SS, FS, or TT process parameter). Eventually, the extrapolation model data set 104 is obtained and configured as the target model data set.

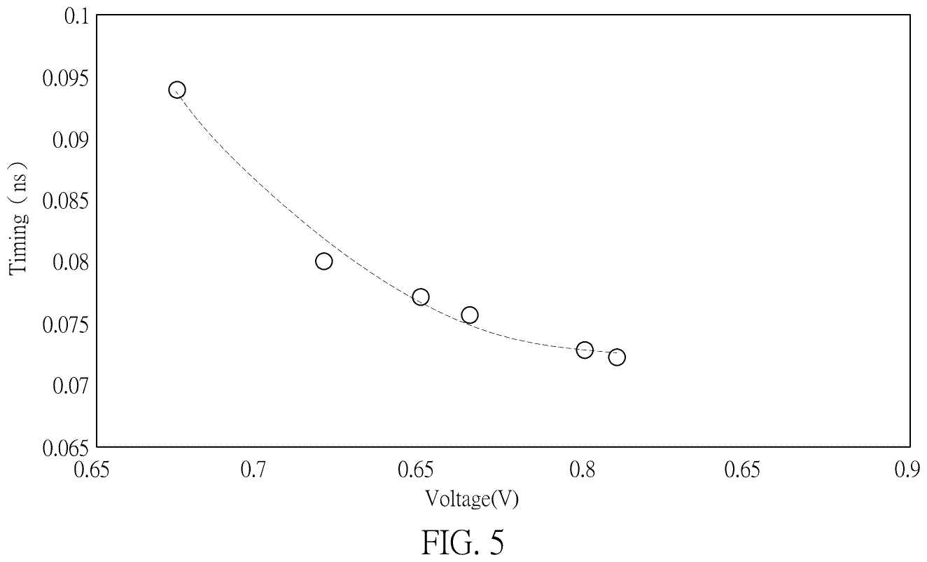

Referring to FIG. 5 to FIG. 8, FIG. 5 to FIG. 8 are each a schematic diagram showing trend analysis according to one embodiment of the present disclosure. FIG. 5 shows a fitting curve y1(x) generated by performing fitting with the quadratic equation and on timing data of six integrated circuit model data sets (which correspond to different voltage parameter values). The fitting curve y1(x) is shown as follows: y1(x)=1.1899x²−1.9194x+0.8467.

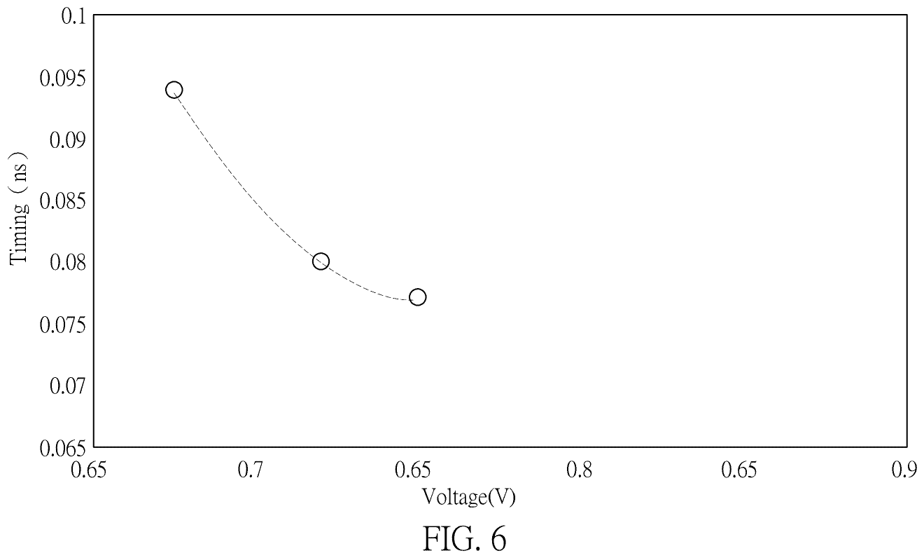

FIG. 6 shows a fitting curve y2(x) generated by performing fitting on the timing data of the former three integrated circuit model data sets (a low-voltage region). The fitting curve y2(x) is shown as follows: y2(x)=2.8x²−4.2127x+1.6616.

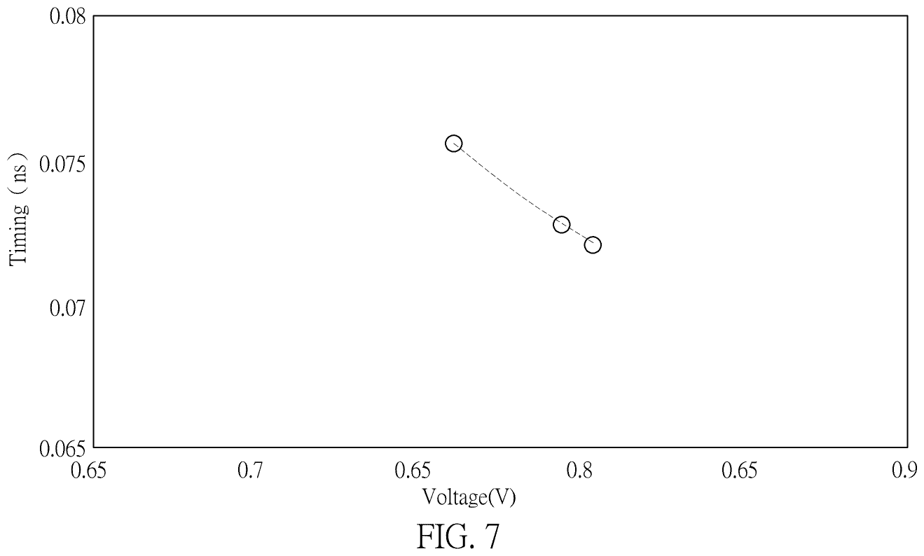

FIG. 7 shows a fitting curve y3(x) generated by performing fitting on the timing data of the latter three integrated circuit model data sets (a high-voltage region). The fitting curve y3(x) is shown as follows: y3(x)=0.2222×2-0.4278x+0.2729.

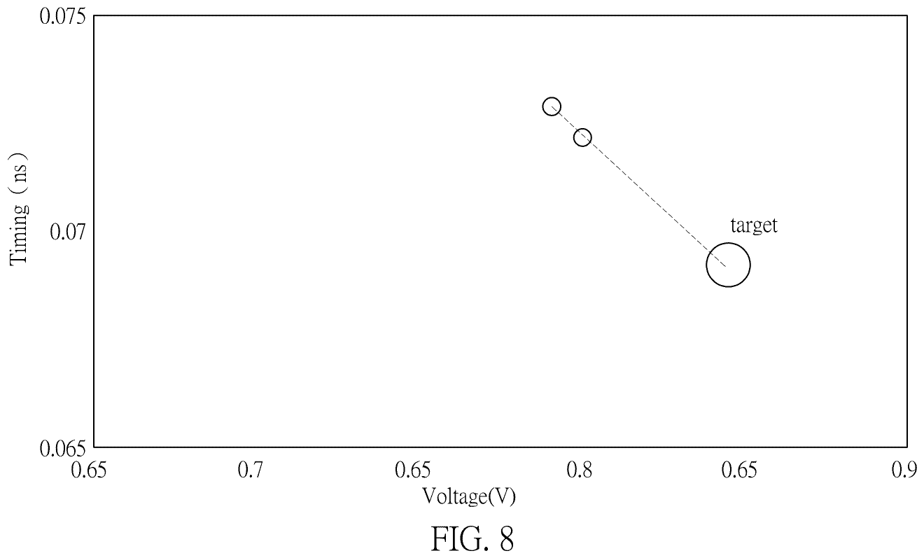

FIG. 8 shows a fitting curve y4(x) generated by performing fitting on the timing data of the last two integrated circuit model data sets and a voltage and timing data that correspond to a target integrated circuit model data set. The fitting curve y4(x) is shown as follows: y4(x)=0.101x²−0.2326x+0.1944.

After second-order differentiation is performed on all the fitting curves, y1″(x), y2″(x), y3″(x), and y4″(x) are respectively determined to be c1, c2, c3, and c4, and to be 1.1899, 2.8, 0.2222, and 0.101. It can be observed from the behavior of the fitting curves that the behavior of a curve in the high-voltage region most approximates an ideal fitting target. As such, by filtering out the key region closest to the target parameter value and increasing a data amount in the key region, the accuracy of the target integrated circuit model data set generated after execution of the extrapolation procedure can be enhanced in the present disclosure.

Referring to Table 1 below, Table 1 shows three examples where different integrated circuit data sets are used for fitting. In Example 1, three reference parameter values (i.e., 0.675, 0.765, and 0.810) are used to perform fitting on a target parameter value (i.e., 0.855). In Example 2, six reference parameter values (which include all parameter values and an interpolation parameter value) are used to perform fitting on the target parameter value (i.e., 0.855). In Example 3, the generation method of the present disclosure is adopted, and the two reference parameter values (i.e., 0.765 and 0.810) closest to the target parameter value are used to generate the interpolation parameter value (i.e., 0.80). Afterwards, these three values are used to perform fitting on the target parameter value (i.e., 0.855).

TABLE 1

| | Voltage (V) | | | | | | |
|---|---|---|---|---|---|---|---|
| | | | | | 0.80 | | |
| | | | | | (interpolation | | |
| | | | | | parameter | | |
| Example | 0.675 | 0.72 | 0.75 | 0.765 | value) | 0.810 | 0.855 |
| Example | V | X | X | V | X | V | target parameter |
| 1 | | | | | | | value |
| Example | V | V | V | V | V | V | target parameter |
| 2 | | | | | | | value |
| Example | X | X | X | V | V | V | target parameter |
| 3 | | | | | | | value |

Referring to Table 2 below, Table 2 shows relative errors (in the form of percentage) and the required execution time for the timing data (which includes setup time, hold time, etc.) of the three examples in Table 1, and shows execution time of a conventional process of library re-characterization (re-K). It can be observed from Table 2 that, in the integrated circuit model data set provided in the present disclosure, the execution time can be far less than that of the conventional process of library re-characterization (re-K), and the accuracy is also way better than a fitting method that adopts a large amount of integrated circuit model data sets or does not filter out the key region. The achievable accuracy can even have an error of less than 1%.

TABLE 2

Timing

| | Setup | Hold | Execution Time |
|---|---|---|---|
| | relative error (%) | | (minute/seccond) |
| Example 1 | −1.93 | −1.98 | 13 s |
| Example 2 | −1.79 | −1.92 | 27 s |
| Example 3 | −0.63 | −0.73 | 26 s |
| Conventional re-K | — | — | 38 min and 45 s |

### Beneficial Effects of the Embodiment

In conclusion, in the generation method and the generation device of the integrated circuit model data set provided by the present disclosure, the recursive machine learning model can be used to produce a high-precision integrated circuit model data set by way of interpolation and extrapolation. Accordingly, simulation time and computing resources can be saved, and a design schedule of an integrated circuit can be accelerated.

Furthermore, since the generation method and the generation device of the present disclosure can provide the high-precision integrated circuit model data set at an early stage of circuit configuration and development, back-and-forth debugging can be reduced, and a schedule for modifying a circuit can be shortened. The designed circuit can also closely reflect an actual analysis result thereof, thereby having improved efficacy, power consumption, and area performance.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A generation method of an integrated circuit model data set, which is performed by a generation device that includes at least one processor and a memory, the generation method comprising processes of:
obtaining a plurality of reference model data sets that correspond to different parameter combinations;
analyzing the plurality of reference model data sets to generate a reference data trend, and determining a key region according to a target parameter value of a target parameter;
obtaining a plurality of filtered model data sets after the plurality of reference model data sets are filtered according to the reference data trend and the key region; and
inputting the plurality of filtered model data sets into a recursive machine learning model, wherein the recursive machine learning model is configured to sequentially execute an interpolation procedure and an extrapolation procedure, so as to generate a target model data set;
wherein, in the interpolation procedure, the recursive machine learning model generates an interpolation model data set according to the plurality of filtered model data sets; wherein, in the extrapolation procedure, the recursive machine learning model generates an extrapolation model data set that corresponds to the target parameter value according to the plurality of filtered model data sets and the interpolation model data set, and the extrapolation model data set is configured as the target model data set.

2. The generation method according to claim 1, wherein each of the parameter combinations includes a process parameter value, a voltage parameter value, and a temperature parameter value that respectively correspond to a process parameter, a voltage parameter, and a temperature parameter.

3. The generation method according to claim 2, wherein the target parameter is the process parameter, the voltage parameter, or the temperature parameter.

4. The generation method according to claim 1, wherein a quantity of the plurality of reference model data sets is three or more.

5. The generation method according to claim 1, wherein the process of analyzing the plurality of reference model data sets to generate the reference data trend includes:
obtaining a plurality of reference parameter values of the plurality of reference model data sets that correspond to the target parameter, and obtaining model data that corresponds to the plurality of reference parameter values of the plurality of reference model data sets; wherein the model data is configured as the reference data trend.

6. The generation method according to claim 5, wherein the process of obtaining the plurality of filtered model data sets after the plurality of reference model data sets are filtered according to the reference data trend and the key region includes:
identifying, according to the reference data trend, two of the plurality of reference parameter values closest to the target parameter value; and configuring two of the plurality of reference model data sets that correspond to the two of the plurality of reference parameter values as the plurality of filtered model data sets.

7. The generation method according to claim 5, wherein the key region is defined by two of the plurality of reference parameter values closest to the target parameter value.

8. The generation method according to claim 7, wherein, in the interpolation procedure, the interpolation model data set generated by the recursive machine learning model has an interpolation parameter value that corresponds to the target parameter, and the interpolation parameter value falls between the two of the plurality of reference parameter values closest to the target parameter value.

9. The generation method according to claim 8, wherein, in the interpolation procedure, the recursive machine learning model performs fitting on the plurality of reference parameter values and the model data that correspond to the plurality of filtered model data sets for generating a first fitting equation, and the interpolation parameter value that falls between the two of the plurality of reference parameter values closest to the target parameter value in the first fitting equation and model data that corresponds to the interpolation parameter value are obtained for generating the interpolation model data set.

10. The generation method according to claim 9, wherein, in the extrapolation procedure, the recursive machine learning model performs fitting on the plurality of reference parameter values and the model data that correspond to the plurality of filtered model data sets and on the interpolation parameter value and the model data that correspond to the interpolation model data set for generating a second fitting equation, and model data that corresponds to the target parameter value in the second fitting equation is obtained, so that the extrapolation model data set is generated according to the model data that corresponds to the target parameter value and is configured as the target model data set.

11. A generation device of an integrated circuit model data set, comprising:
at least one processor and a memory, wherein the at least one processor is configured to access the memory and execute processes of:
obtaining a plurality of reference model data sets that correspond to different parameter combinations;
analyzing the plurality of reference model data sets to generate a reference data trend, and determining a key region according to a target parameter value of a target parameter;
obtaining a plurality of filtered model data sets after the plurality of reference model data sets are filtered according to the reference data trend and the key region; and
inputting the plurality of filtered model data sets into a recursive machine learning model, wherein the recursive machine learning model is configured to sequentially execute an interpolation procedure and an extrapolation procedure, so as to generate a target model data set;
wherein, in the interpolation procedure, the recursive machine learning model generates an interpolation model data set according to the plurality of filtered model data sets; wherein, in the extrapolation procedure, the recursive machine learning model generates an extrapolation model data set that corresponds to the target parameter value according to the plurality of filtered model data sets and the interpolation model data set, and the extrapolation model data set is configured as the target model data set.

12. The generation device according to claim 11, wherein each of the parameter combinations includes a process parameter value, a voltage parameter value, and a temperature parameter value that respectively correspond to a process parameter, a voltage parameter, and a temperature parameter.

13. The generation device according to claim 12, wherein the target parameter is the process parameter, the voltage parameter, or the temperature parameter.

14. The generation device according to claim 11, wherein a quantity of the plurality of reference model data sets is three or more.

15. The generation device according to claim 11, wherein the process of analyzing the plurality of reference model data sets to generate the reference data trend includes:
obtaining a plurality of reference parameter values of the plurality of reference model data sets that correspond to the target parameter, and obtaining model data that corresponds to the plurality of reference parameter values of the plurality of reference model data sets; wherein the model data is configured as the reference data trend.

16. The generation device according to claim 15, wherein the process of obtaining the plurality of filtered model data sets after the plurality of reference model data sets are filtered according to the reference data trend and the key region includes:
identifying, according to the reference data trend, two of the plurality of reference parameter values closest to the target parameter value; and configuring two of the plurality of reference model data sets that correspond to the two of the plurality of reference parameter values as the plurality of filtered model data sets.

17. The generation device according to claim 15, wherein the key region is defined by two of the plurality of reference parameter values closest to the target parameter value.

18. The generation device according to claim 17, wherein, in the interpolation procedure, the interpolation model data set generated by the recursive machine learning model has an interpolation parameter value that corresponds to the target parameter, and the interpolation parameter value falls between the two of the plurality of reference parameter values closest to the target parameter value.

19. The generation device according to claim 18, wherein, in the interpolation procedure, the recursive machine learning model performs fitting on the plurality of reference parameter values and the model data that correspond to the plurality of filtered model data sets for generating a first fitting equation, and the interpolation parameter value that falls between the two of the plurality of reference parameter values closest to the target parameter value in the first fitting equation and model data that corresponds to the interpolation parameter value are obtained for generating the interpolation model data set.

20. The generation device according to claim 19, wherein, in the extrapolation procedure, the recursive machine learning model performs fitting on the plurality of reference parameter values and the model data that correspond to the plurality of filtered model data sets and on the interpolation parameter value and the model data that correspond to the interpolation model data set for generating a second fitting equation, and model data that corresponds to the target parameter value in the second fitting equation is obtained, so that the extrapolation model data set is generated according to the model data that corresponds to the target parameter value and is configured as the target model data set.
